(19) United States
(12) Patent Application Publication
(10) Pub. No.: US 2026/0319472 A1
(43) Pub. Date: Oct. 15, 2026

(54) FILM-THICKNESS ESTIMATING METHOD FOR WORKPIECE AND POLISHING APPARATUS

(71) Applicant: EBARA CORPORATION, Tokyo (JP)

(72) Inventors: Keita YAGI, Tokyo (JP); Yuki WATANABE, Tokyo (JP)

(21) Appl. No.: 19/235,371

(22) Filed: Jun. 11, 2025

(30) Foreign Application Priority Data
Jun. 17, 2024 (JP) 2024-097315

(51) Int. Cl. G05B 19/418; G01B 11/06; H10P 72/00

(52) U.S. Cl. CPC G05B 19/41865; G01B 11/0625; G05B 19/4183; G05B 19/41885; H10P 72/0428; H10P 72/0604; G01B 2210/56; G05B 2219/37345; G05B 2219/37398

(57) ABSTRACT

A technique for automatically determining a film-thickness estimation recipe suitable for workpiece, such as wafer, is disclosed. A film-thickness estimation method for a workpiece, includes: generating a plurality of reference spectra of reflected light from a plurality of reference workpieces during polishing of the plurality of reference workpieces; creating training data containing the plurality of reference spectra and a plurality of recipe labels indicating a plurality of film-thickness estimation recipes determined for the plurality of reference workpieces; performing machine learning using the training data to create a recipe classification model; generating a measurement spectrum of reflected light from a film-thickness measurement point; inputting the measurement spectrum into the recipe classification model and outputting a classification result indicating one of the plurality of recipe labels; and determining one of the plurality of recipe labels based on the classification result.

### CROSS REFERENCE TO RELATED APPLICATION

This document claims priority to Japanese Patent Application No. 2024-097315 filed Jun. 17, 2024, the entire contents of which are hereby incorporated by reference.

### BACKGROUND

Manufacturing process of semiconductor devices includes various steps including polishing of an insulating film such as SiO₂, polishing of a metal film, such as copper, tungsten, etc. Wafer polishing is performed using a polishing apparatus. This polishing apparatus generally includes a polishing table that supports a polishing pad, a polishing head that presses a wafer against the polishing pad, and a slurry supply nozzle that supplies slurry onto the polishing pad. While the polishing table is rotating, the slurry is supplied onto the polishing pad on the polishing table, and the polishing head presses the wafer against the polishing pad. The wafer is brought into sliding contact with the polishing pad in the presence of the slurry. The surface of the wafer is planarized by a combination of a chemical action of the slurry and a mechanical action of abrasive grains contained in the slurry and/or the polishing pad.

Polishing of the wafer is terminated when a thickness of a film (e.g., an insulating film, a metal film, or a silicon layer) constituting the surface of the wafer reaches a predetermined target value. The polishing apparatus generally includes an optical-film thickness measuring system for measuring a thickness of a non-metallic film, such as an insulating film or a silicon layer. This optical-film thickness measuring system is configured to direct light from a light source to the surface of the wafer, measure intensity of reflected light from the wafer with a spectrometer, and estimate a film thickness of the wafer by analyzing a spectrum of the reflected light.

In the above-mentioned film thickness measurement, it is necessary to prepare in advance a film-thickness estimation recipe suitable for the wafer to be polished. When multiple film-thickness estimation recipes are prepared, a task of selecting the optimal film-thickness estimation recipe may be a burden for a user. In addition, human error may occur in which the user selects an incorrect film-thickness estimation recipe.

### SUMMARY

Therefore, there is provided a technique that can automatically determine an optimum film-thickness estimation recipe for a workpiece, such as a wafer.

Embodiments, which will be described below, relate to a technique for estimating a film thickness of a workpiece, such as a wafer, substrate, or panel, based on a spectrum of reflected light from the workpiece, and more particularly to a technique for automatically determining a film-thickness estimation recipe used for film thickness estimation.

In an embodiment, there is provided a film-thickness estimation method for a workpiece, comprising: generating a plurality of reference spectra of reflected light from a plurality of reference workpieces while irradiating the plurality of reference workpieces with light during polishing of the plurality of reference workpieces; creating training data containing the plurality of reference spectra and a plurality of recipe labels indicating a plurality of film-thickness estimation recipes determined for the plurality of reference workpieces; performing machine learning using the training data to create a recipe classification model; generating a measurement spectrum of reflected light from a film-thickness measurement point on a workpiece while irradiating the film-thickness measurement point with light during polishing of the workpiece; inputting the measurement spectrum into the recipe classification model and outputting a classification result indicating one of the plurality of recipe labels from the recipe classification model; determining one of the plurality of recipe labels based on the classification result; and estimating a film thickness of the workpiece using a film-thickness estimation recipe corresponding to the determined recipe label.

In an embodiment, determining one of the plurality of recipe labels based on the classification result comprises determining a recipe label that is majority among a plurality of recipe labels indicated in a plurality of classification results output from the recipe classification model within a predetermined decision time after start of polishing of the workpiece.

In an embodiment, the classification result includes a plurality of confidence scores corresponding to the plurality of recipe labels, respectively.

In an embodiment, the film-thickness estimation method further comprises: when all of the plurality of confidence scores are smaller than a threshold value, updating the training data by adding, to the training data, the measurement spectrum and a new recipe label indicating a new film-thickness measurement recipe determined based on the measurement spectrum; and updating the recipe classification model by performing machine learning using the updated training data.

In an embodiment, the film-thickness measurement point on the workpiece is located within a central region of a surface of the workpiece.

In an embodiment, the plurality of reference spectra are spectra generated during initial stages of polishing of the plurality of reference workpieces.

In an embodiment, each of the plurality of film-thickness estimation recipes includes a recipe parameter for use in film thickness estimation using a film-thickness estimation model created by machine learning.

In an embodiment, there is provided a polishing apparatus for a workpiece, comprising: a polishing table configured to support a polishing pad; a polishing head configured to press a workpiece against the polishing pad to polish the workpiece; an optical sensor head configured to irradiate a film-thickness measurement point on the workpiece with light and receive reflected light from the film-thickness measurement point during polishing of the workpiece; and a processing system configured to generate a measurement spectrum of the reflected light, the processing system including: training data containing a plurality of reference spectra of reflected light from a plurality of reference workpieces and a plurality of recipe labels indicating a plurality of film-thickness estimation recipes determined for the plurality of reference workpieces, respectively; and a recipe classification model created by machine learning using the training data, wherein the processing system is configured to: input the measurement spectrum into the recipe classification model during polishing of the workpiece; output a classification result indicating one of the plurality of recipe labels from the recipe classification model; determine one of the plurality of recipe labels based on the classification result; and estimate a film thickness of the workpiece using a film-thickness estimation recipe corresponding to the determined recipe label.

The above-described embodiments can make it possible to automatically select an optimal film-thickness estimation recipe based on the classification results output from the recipe classification model.

### BRIEF DESCRIPTION OF THE DRAWINGS

FIG. 1 is a schematic diagram showing an embodiment of a polishing apparatus;

FIG. 2 is a cross-sectional view showing a detailed configuration of an optical film-thickness measuring device;

FIG. 3 is a schematic diagram showing an example of a measurement spectrum generated from light-intensity measurement data;

FIG. 4 is a diagram showing an example of film-thickness measurement points with light on a workpiece;

FIG. 5 is a diagram explaining a function of a recipe classification model;

FIG. 6 is a schematic diagram showing an embodiment of a recipe classification model composed of a Bayesian neural network;

FIG. 7 is a flowchart explaining an embodiment of creating the recipe classification model;

FIG. 8 is a table showing an example of multiple classification results output from the recipe classification model within a predetermined decision time after polishing of a workpiece begins;

FIG. 9 is a schematic diagram showing an example in which the recipe classification model outputs the same confidence scores for multiple recipe labels; and

FIG. 10 is a flowchart explaining an embodiment of estimating a film thickness of a workpiece using the recipe classification model.

### DESCRIPTION OF EMBODIMENTS

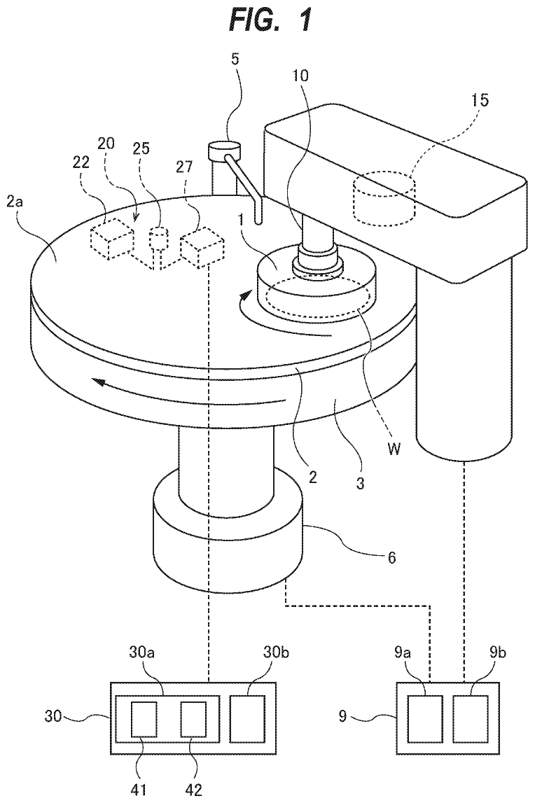

Hereinafter, embodiments will be described with reference to the drawings. FIG. 1 is a schematic diagram showing an embodiment of a polishing apparatus. As shown in FIG. 1, the polishing apparatus includes a polishing table 3 configured to support a polishing pad 2, a polishing head 1 configured to press a workpiece W against the polishing pad 2, a table motor 6 configured to rotate the polishing table 3, a polishing-liquid supply nozzle 5 configured to supply a polishing liquid (e.g., slurry) onto the polishing pad 2, and an operation controller 9 configured to control operation of the polishing apparatus. The polishing pad 2 has an upper surface that constitutes a polishing surface 2a for polishing the workpiece W. The workpiece W has a film that constitutes an interconnect structure on its surface. Examples of the workpiece W include wafer, substrate, interconnect substrate, quadrilateral substrate, etc. for use in manufacturing of semiconductor devices. In one example, the workpiece W is a product wafer on which a multilayer film or a single layer film is formed.

The polishing head 1 is coupled to a head shaft 10, and the head shaft 10 is coupled to a polishing-head rotating device 15. The polishing-head rotating device 15 is configured to rotate the polishing head 1 together with the head shaft 10 in a direction indicated by arrow. Although configuration of the polishing-head rotating device 15 is not particularly limited, in one example, the polishing-head rotating device 15 includes an electric motor, a belt, a pulley, etc. The polishing table 3 is coupled to the table motor 6, and the table motor 6 is configured to rotate the polishing table 3 and the polishing pad 2 in a direction indicated by arrow. The polishing head 1, the polishing-head rotating device 15, and the table motor 6 are coupled to the operation controller 9.

The workpiece W is polished as follows. The polishing liquid is supplied from the polishing-liquid supply nozzle 5 onto the polishing surface 2a of the polishing pad 2 on the polishing table 3, while the table motor 6 and the polishing-head rotating device 15 rotate the polishing table 3 and the polishing head 1, respectively, in the directions shown by the arrows in FIG. 1. While the workpiece W is rotated by the polishing head 1, the workpiece W is pressed against the polishing surface 2a of the polishing pad 2 by the polishing head 1 with the polishing liquid present on the polishing pad 2. A surface of the workpiece W is polished by a chemical action of the polishing liquid and a mechanical action of abrasive grains contained in the polishing liquid and/or the polishing pad 2.

The operation controller 9 includes a memory 9a in which programs are stored, and an arithmetic device 9b configured to execute arithmetic operations according to instructions included in the programs. The operation controller 9 includes at least one computer. The memory 9a includes a main memory, such as a random access memory (RAM), and an auxiliary memory, such as a hard disk drive (HDD) or a solid state drive (SSD). Examples of the arithmetic device 9b include a central processing unit (CPU) and a graphic processing unit (GPU). However, the specific configuration of the operation controller 9 is not limited to these examples.

The polishing apparatus includes an optical film-thickness measuring device 20 for measuring a film thickness of the workpiece W. The optical film-thickness measuring device 20 includes a light source 22 configured to emit light, an optical sensor head 25 configured to irradiate the workpiece W with the light from the light source 22 and receive reflected light from the workpiece W, a spectrometer 27 coupled to the optical sensor head 25, and a processing system 30 configured to measure the film thickness of the workpiece W based on a spectrum of the reflected light from the workpiece W. The optical sensor head 25 is disposed in the polishing table 3 and rotates together with the polishing table 3.

The processing system 30 includes a memory 30a that stores programs, a film-thickness estimation model 41, and a recipe classification model 42 therein, and an arithmetic device 30b configured to execute arithmetic operations according to instructions included in the program. The processing system 30 includes at least one computer. The memory 30a includes a main memory, such as a random access memory (RAM), and an auxiliary memory, such as a hard disk drive (HDD) or a solid state drive (SSD). Examples of the arithmetic device 30b include a central processing unit (CPU) and a graphic processing unit (GPU). However, the specific configuration of the processing system 30 is not limited to these examples.

Each of the operation controller 9 and the processing system 30 may be composed of a plurality of computers. For example, each of the operation controller 9 and the processing system 30 may be composed of a combination of an edge server and a cloud server. In one embodiment, the operation controller 9 and the processing system 30 may be composed of a single computer.

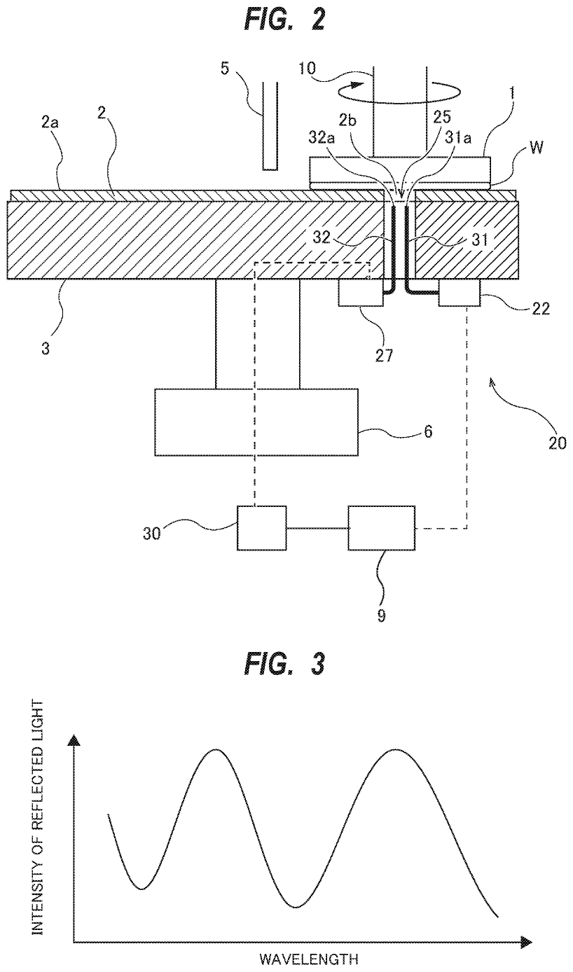

FIG. 2 is a cross-sectional view showing a detailed configuration of the optical film-thickness measuring device 20. The optical film-thickness measuring device 20 includes a light-emitting optical fiber cable 31 coupled to the light source 22, and a light-receiving optical fiber cable 32 coupled to the spectrometer 27. A distal end 31a of the light-emitting optical fiber cable 31 and a distal end 32a of the light-receiving optical fiber cable 32 constitute the optical sensor head 25. Specifically, the light-emitting optical fiber cable 31 directs the light emitted by the light source 22 to the workpiece W on the polishing pad 2, and the light-receiving optical fiber cable 32 receives the reflected light from the workpiece W and transmits the reflected light to the spectrometer 27.

The spectrometer 27 is coupled to the processing system 30. The light-emitting optical fiber cable 31, the light-receiving optical fiber cable 32, the light source 22, and the spectrometer 27 are attached to the polishing table 3 and rotate together with the polishing table 3 and the polishing pad 2. The optical sensor head 25, which is constituted by the distal end 31a of the light-emitting optical fiber cable 31 and the distal end 32a of the light-receiving optical fiber cable 32, is disposed so as to face the surface of the workpiece W on the polishing pad 2.

The optical sensor head 25 is arranged at a position where the optical sensor head 25 moves across the surface of the workpiece W on the polishing pad 2 each time the polishing table 3 and the polishing pad 2 make one rotation. The polishing pad 2 has a through-hole 2b located over the optical sensor head 25. The optical sensor head 25 irradiates the workpiece W with the light through the through-hole 2b each time the polishing table 3 makes one rotation, and receives the reflected light from the workpiece W through the through-hole 2b.

In one embodiment, a flow of pure water may be formed in the through-hole 2b of the polishing pad 2 so as to prevent the polishing liquid and polishing debris from contacting the optical sensor head 25. The light is emitted from the optical sensor head 25 through the pure water to the workpiece W, and the reflected light from the workpiece W travels through the pure water and is received by the optical sensor head 25. In another embodiment, a transparent window (not shown) may be fitted in the through-hole 2b of the polishing pad 2. The transparent window is made of a material (e.g., transparent resin) that allows the light to pass therethrough. In this case, the light is emitted from the optical sensor head 25 to the workpiece W through the transparent window, and the reflected light from the workpiece W travels through the transparent window and is received by the optical sensor head 25.

The light source 22 may be a flash light source that repeatedly emits light at short time intervals. An example of the light source 22 is a xenon flash lamp. The light source 22 is electrically coupled to the operation controller 9, and emits the light upon receiving a trigger signal sent from the operation controller 9. More specifically, while the optical sensor head 25 sweeps across the surface of the workpiece W on the polishing pad 2, the light source 22 receives multiple trigger signals and emits the light multiple times. Therefore, each time the polishing table 3 makes one rotation, the light is directed onto multiple film-thickness measurement points on the workpiece W, including a central point of the workpiece W.

The light emitted by the light source 22 is transmitted to the optical sensor head 25. Specifically, the light is transmitted to the optical sensor head 25 through the light-emitting optical fiber cable 31 and is emitted from the optical sensor head 25. The light passes through the through-hole 2b of the polishing pad 2 and is incident on the workpiece W on the polishing pad 2. The reflected light from the workpiece W passes through the through-hole 2b of the polishing pad 2 again and is received by the optical sensor head 25. The reflected light from the workpiece W is transmitted to the spectrometer 27 through the light-receiving optical fiber cable 32.

The spectrometer 27 is configured to resolve or decompose the reflected light according to its wavelength and measure intensity of the reflected light at each wavelength over a predetermined wavelength range. Specifically, the spectrometer 27 resolves the reflected light from the workpiece W according to wavelength and measures the intensity of the reflected light at each wavelength over a predetermined wavelength range to generate light-intensity measurement data. The intensity of the reflected light at each wavelength may be expressed as a relative value, such as reflectance or relative reflectance. The light-intensity measurement data is sent to the processing system 30.

From the light-intensity measurement data, the processing system 30 generates a spectrum of the reflected light, as shown in FIG. 3. In the following description, the spectrum of the reflected light from the workpiece W is referred to as measurement spectrum. The measurement spectrum of the reflected light from the workpiece W includes information on a film thickness of the workpiece W. In other words, the measurement spectrum of the reflected light varies depending on the film thickness of the workpiece W. The processing system 30 is configured to determine the film thickness of the workpiece W based on the measurement spectrum of the reflected light. In one embodiment, the processing system 30 inputs the measurement spectrum of the reflected light into the film-thickness estimation model 41 and outputs an estimated value of the film thickness of the workpiece W from the film-thickness estimation model 41.

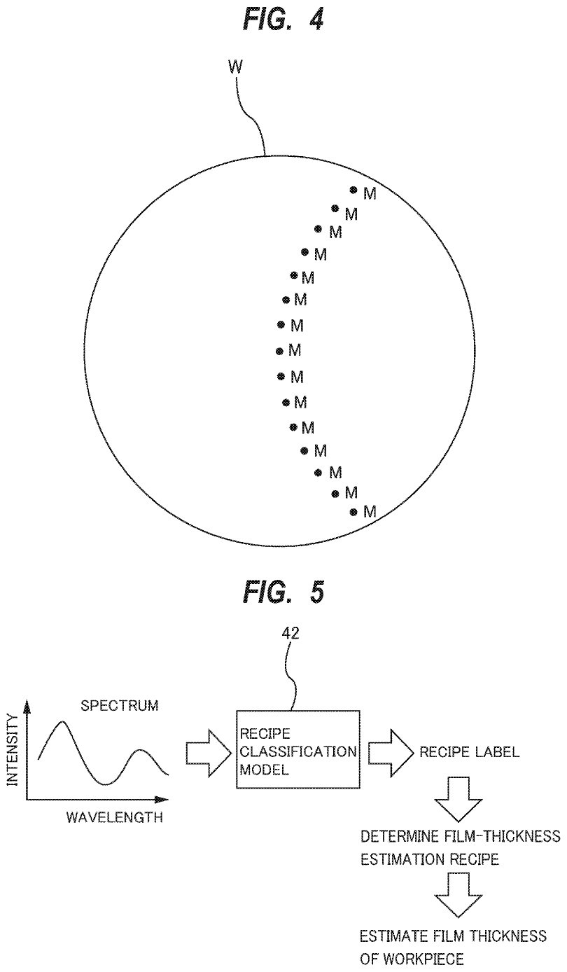

FIG. 4 is a diagram showing an example of a plurality of film-thickness measurement points on the workpiece W. As described above, during polishing of the workpiece W, the optical sensor head 25 irradiates the surface of the workpiece W with the light multiple times while the optical sensor head 25 is moving across the surface of the workpiece W, each time the polishing table 3 makes one rotation. Therefore, as shown in FIG. 4, a plurality of film-thickness measurement points M are irradiated with the light from the optical sensor head 25 and are aligned in a radial direction of the workpiece W on the surface of the workpiece W. One of the plurality of film-thickness measurement points M is located on the central point of the workpiece W. Each time the polishing table 3 makes one rotation, the optical sensor head 25 receives the reflected light from the plurality of film-thickness measurement points M, and the processing system 30 generates a plurality of measurement spectra of the reflected light from the plurality of film-thickness measurement points M.

The processing system 30 is configured to determine a plurality of film thicknesses at the plurality of film-thickness measurement points M from the plurality of measurement spectra of the reflected light. In one embodiment, the processing system 30 is configured to input each measurement spectrum to the film-thickness estimation model 41 stored in the memory 30a, and output an estimated value of the film thickness from the film-thickness estimation model 41. The film-thickness estimation model 41 is a trained model created by machine learning.

The machine learning of the film-thickness estimation model 41 is performed as follows. Film-thickness-estimation training data including a plurality of spectra generated during polishing of a sample and corresponding measured film thicknesses are prepared. The corresponding measured film thicknesses are correct labels or ground-truth labels used in the machine learning. The processing system 30 performs the machine learning using the film-thickness-estimation training data. Specifically, the processing system 30 inputs a spectrum to the film-thickness estimation model 41, and outputs a film thickness corresponding to the spectrum from the film-thickness estimation model 41. The processing system 30 compares the film thickness output from the film-thickness estimation model 41 with the ground-truth label corresponding to the input sample, and adjusts parameters (weights, thresholds, etc.) of each node (neuron) so as to minimize an error between the film thickness output from the film-thickness estimation model 41 and the corresponding ground-truth label. In this way, the film-thickness estimation model 41 is trained to output an appropriate film thickness based on the spectrum input to the film-thickness estimation model 41.

The processing system 30 inputs the measurement spectrum generated during polishing of the workpiece W to the film-thickness estimation model 41, and outputs a film thickness of the workpiece W from the film-thickness estimation model 41. In one embodiment, the processing system 30 may perform pre-processing on the measurement spectrum before the measurement spectrum is input to the film-thickness estimation model 41. The pre-processing is performed for the purpose of reducing a variation of a plurality of measurement spectra and allowing the film-thickness estimation model 41 to output a correct film thickness. Examples of the pre-processing include smoothing of measurement spectra and normalization of measurement spectra. An example of smoothing is a moving average of measurement spectra.

The pre-processing is performed according to a recipe parameter included in the film-thickness estimation recipe. For example, in the case of the moving average of measurement spectra, a calculation time of the moving average is included as a recipe parameter in the film-thickness estimation recipe. The processing system 30 calculates an average of measurement spectra within the calculation time according to the film-thickness estimation recipe, inputs the obtained average as a measurement spectrum to the film-thickness estimation model 41, and outputs an estimated value of the film thickness from the film-thickness estimation model 41. However, the recipe parameter is not limited to the calculation time of the moving average, and may include other parameter.

In one embodiment, the processing system 30 may determine (or estimate) the film thickness of the workpiece W using a known film thickness estimation technique, instead of the film-thickness estimation model 41. For example, the processing system 30 determines, from a reference spectral library, a reference spectrum that has a shape that is closest to a shape of the measurement spectrum of the reflected light, and determines a film thickness associated with the determined reference spectrum. In another example, the processing system 30 performs a Fourier transform on the measurement spectrum of the reflected light, and determines a film thickness from a resulting frequency spectrum.

The process of determining (or estimating) the film thickness in the above-mentioned known film thickness estimation technique is also performed according to recipe parameters included in the film-thickness estimation recipe. For example, the recipe parameters include a time width for calculating a moving average of a plurality of measurement spectra acquired during polishing of the workpiece W, the number of data points for calculating a spatial average of a plurality of measurement spectra acquired during polishing of the workpiece W, a parameter of a filter applied to a plurality of measurement spectra acquired during polishing of the workpiece W, a normalization parameter for normalizing a plurality of measurement spectra acquired during polishing of the workpiece W, a wavelength range of a measurement spectrum used to determine a film thickness, and a reference spectrum group number in a reference spectral library including a reference spectrum used to determine a film thickness (see Japanese laid-open patent publication No. 2021-3789).

The film-thickness estimation recipe may vary depending on the type of workpiece W to be polished. More specifically, it is necessary to select an optimal film-thickness estimation recipe according to a surface structure of the workpiece W to be polished. Thus, the processing system 30 is configured to determine an optimal film-thickness estimation recipe for the workpiece W using the recipe classification model 42 stored in the memory 30a. The recipe classification model 42 is a trained model created by machine learning.

FIG. 5 is a diagram illustrating a function of the recipe classification model 42. As shown in FIG. 5, while the film-thickness measurement point on the workpiece W is irradiated with the light during polishing of the workpiece W, the processing system 30 generates the measurement spectrum of the reflected light from the film-thickness measurement point, inputs the measurement spectrum to the recipe classification model 42, outputs a recipe label from the recipe classification model 42, and estimates a film thickness of the workpiece W using a film-thickness estimation recipe associated in advance with the recipe label.

An embodiment of creating the recipe classification model 42 will be described below. First, training data for use in machine learning of the recipe classification model 42 is produced. Specifically, polishing apparatus is used to polish a plurality of reference workpieces one by one. During polishing of the plurality of reference workpieces, a plurality of reference spectra of reflected light from the plurality of reference workpieces are generated while the plurality of reference workpieces are irradiated with light. The plurality of reference workpieces have different surface structures. Therefore, the plurality of reference spectra of the reflected light from the plurality of reference workpieces have different shapes (or features).

More specifically, during polishing of a first reference workpiece, the optical sensor head 25 emits the light onto a plurality of first measurement points (see the plurality of film-thickness measurement points M in FIG. 4) on the first reference workpiece, while the optical sensor head 25 receives reflected light from the plurality of first measurement points, the spectrometer measures intensity of each reflected light at each wavelength, and the processing system 30 generates a plurality of first reference spectra from the light-intensity measurement data.

The processing system 30 creates a first recipe label indicating a first film-thickness estimation recipe determined for the first reference workpiece. The first film-thickness estimation recipe is determined by a user based on the plurality of first reference spectra. The first recipe label is a correct label or ground-truth label for the plurality of first reference spectra. In the same manner, the plurality of reference workpieces including a second reference workpiece, a third reference workpiece, . . . are polished by the polishing apparatus. The processing system 30 creates a plurality of recipe labels (i.e., a plurality of correct labels or ground-truth labels) corresponding to a plurality of film-thickness estimation recipes, respectively, suitable for the plurality of reference workpieces.

The polishing of the plurality of reference workpieces may be performed by the polishing apparatus shown in FIGS. 1 and 2, or may be performed by a plurality of polishing apparatuses having the same configuration as the polishing apparatus shown in FIGS. 1 and 2. The number of reference workpieces used to create the training data is not particularly limited. In one embodiment, the plurality of reference spectra may be generated while two reference workpieces having different surface structures are polished, two film-thickness estimation recipes may be created from the plurality of reference spectra obtained, and two recipe labels indicating the two film-thickness estimation recipes may be created.

The processing system 30 creates the training data containing the plurality of reference spectra generated during polishing of the plurality of reference workpieces and the plurality of recipe labels indicating the plurality of film-thickness estimation recipes determined for the plurality of reference workpieces, respectively. In one embodiment, the plurality of reference spectra included in the training data are spectra generated in initial stages of polishing of the plurality of reference workpieces. This is because the recipe classification model 42 is used in an initial stage of polishing of the workpiece W, as described below.

The processing system 30 creates the recipe classification model 42 by performing machine learning using the training data. More specifically, the processing system 30 inputs each reference spectrum to the recipe classification model 42, and outputs a recipe label corresponding to the reference spectrum from the recipe classification model 42. The processing system 30 compares the recipe label output from the recipe classification model 42 with a correct label or grand-truth label corresponding to the input reference spectrum, and adjusts parameters (weights, thresholds, etc.) of each node (neuron) so as to eliminate an error between the recipe label output from the recipe classification model 42 and the corresponding grand-truth label.

In this manner, the recipe classification model 42 is trained to output an appropriate recipe label based on a reference spectrum input to the recipe classification model 42. Since each recipe label is associated in advance with a corresponding film-thickness estimation recipe, the processing system 30 can determine an optimal film-thickness estimation recipe corresponding to the recipe label output from the recipe classification model 42.

Examples of the machine learning for creating the recipe classification model 42 include SVR (support vector regression) method, PLS (partial least squares) method, deep learning, random forest, and decision tree method. In one embodiment, the recipe classification model 42 is constituted of a Bayesian neural network created by deep learning. The Bayesian neural network is configured to output a plurality of confidence scores corresponding to the plurality of recipe labels, respectively, as a classification result of the recipe label.

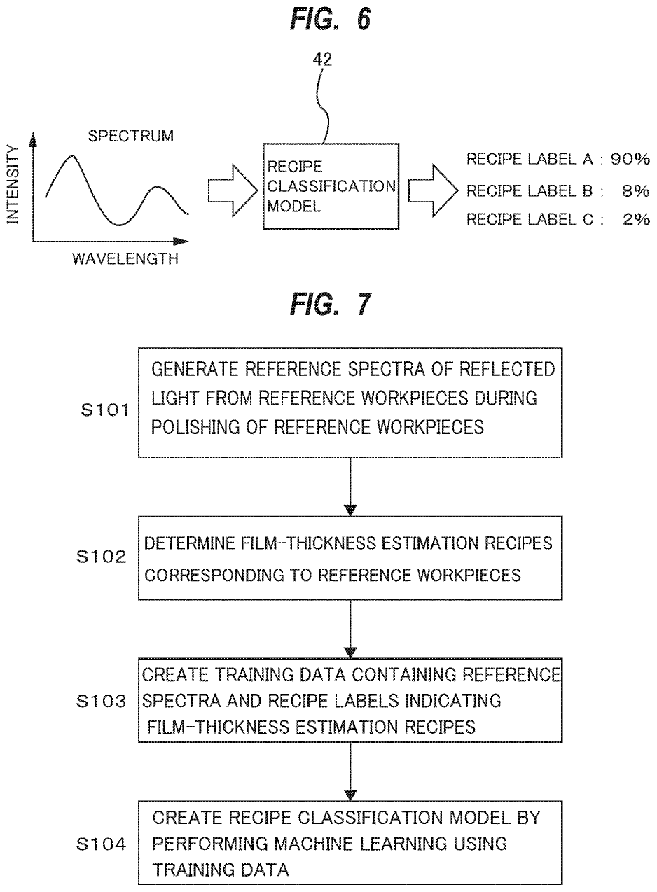

FIG. 6 is a schematic diagram showing an embodiment of the recipe classification model 42 constituted of the Bayesian neural network. When a certain spectrum is input to the recipe classification model 42, the recipe classification model 42 outputs a plurality of confidence scores (%) corresponding to a plurality of recipe labels A, B, and C, respectively. The plurality of recipe labels A, B, and C are recipe labels contained in the training data used for the machine learning of the recipe classification model 42.

In the example shown in FIG. 6, the confidence score of the recipe label A is 90%, the confidence score of the recipe label B is 8%, and the confidence score of the recipe label C is 2%. Since the confidence score of the recipe label A is the highest, the processing system 30 determines that the film-thickness estimation recipe suitable for the input spectrum is the film-thickness estimation recipe A corresponding to the recipe label A.

FIG. 7 is a flow chart illustrating an embodiment of creating the recipe classification model 42.

In step S101, during polishing of the plurality of reference workpieces, the processing system 30 generates the plurality of reference spectra of the reflected light from the plurality of reference workpieces, while the plurality of reference workpieces are irradiated with the light from the optical sensor head 25. The plurality of reference spectra obtained are stored in the memory 30a of the processing system 30.

In step S102, the user determines (or produces) the plurality of film-thickness estimation recipes corresponding to the plurality of reference workpieces, respectively, based on the plurality of reference spectra obtained for the plurality of reference workpieces. Each film-thickness estimation recipe includes, for example, recipe parameters (e.g., the calculation time of moving average) used in pre-processing performed before the input to the film-thickness estimation model 41. In another example, the recipe parameters included in each film-thickness estimation recipe include at least one of a time width for calculating a moving average of reference spectra, the number of data points for calculating a spatial average of reference spectra, a parameter of a filter applied to reference spectra, a normalization parameter for normalizing reference spectra, and a wavelength range of a reference spectrum used to determine a film thickness. The plurality of film-thickness estimation recipes determined by the user are used as the correct labels (or grand-truth labels) in the machine learning.

In step S103, the processing system 30 creates the training data containing the plurality of reference spectra generated in the step S101 and a plurality of recipe labels indicating the plurality of film-thickness estimation recipes determined in the step S102.

In step S104, the processing system 30 creates the recipe classification model 42 by performing the machine learning using the training data created in the step S103. The recipe classification model 42 is stored as a trained model in the memory 30a.

Using the recipe classification model 42 created by the machine learning, the processing system 30 determines a film-thickness estimation recipe suitable for the workpiece W during polishing of the workpiece W, and estimates a film thickness according to the film-thickness estimation recipe. Specifically, while the workpiece W is polished by the polishing apparatus shown in FIGS. 1 and 2, the optical sensor head 25 emits the light to the plurality of film-thickness measurement points (see FIG. 4) on the workpiece W and receives the plurality of reflected lights from the plurality of film-thickness measurement points, and the spectrometer 27 measures the intensity at each wavelength of each reflected light. The processing system 30 generates the plurality of measurement spectra of the reflected lights from the plurality of film-thickness measurement points from the light-intensity measurement data.

The processing system 30 inputs each measurement spectrum to the recipe classification model 42, and outputs a classification result indicating one of the plurality of recipe labels from the recipe classification model 42. For example, when the training data used in the machine learning of the recipe classification model 42 includes three recipe labels A, B, and C, the recipe classification model 42 outputs a classification result indicating one of the recipe labels A, B, and C. In one embodiment, as shown in FIG. 6, the recipe classification model 42 outputs a plurality of confidence scores (%) corresponding to the plurality of recipe labels A, B, and C, respectively.

The processing system 30 determines a recipe label based on the classification result. In the example shown in FIG. 6, the recipe label A with the highest confidence score is the recipe label suitable for the measurement spectrum that was input to the recipe classification model 42. The processing system 30 estimates the film thickness of the workpiece W using the film-thickness estimation recipe corresponding to the determined recipe label. In one embodiment, the processing system 30 performs the pre-processing on the measurement spectrum according to the recipe parameters indicated in the film-thickness estimation recipe, inputs the resultant measurement spectrum to the film-thickness estimation model 41, and outputs an estimated value of the film thickness of the workpiece W from the film-thickness estimation model 41. In another embodiment, the processing system 30 uses the recipe parameters indicated in the film-thickness estimation recipe to determine, from a reference spectral library, a reference spectrum that is closest in shape to the measurement spectrum of the reflected light, and determines a film thickness associated with the determined reference spectrum. In yet another embodiment, the processing system 30 uses the recipe parameters indicated in the film-thickness estimation recipe to perform a Fourier transform on the measurement spectrum of the reflected light, and determines a film thickness from a frequency spectrum obtained.

The determination of the recipe label based on the classification result is performed at an initial stage of polishing the workpiece W. Once the recipe label is determined, the processing system 30 estimates the film thickness of the workpiece W using the film-thickness estimation recipe associated with the determined recipe label until a polishing endpoint of the workpiece W is reached.

In one embodiment, the initial stage of polishing the workpiece W is from a start of polishing the workpiece W to a predetermined decision time. The processing system 30 determines the recipe label (i.e., the film-thickness estimation recipe) based on the classification result output from the recipe classification model 42 within the predetermined decision time after the start of polishing the workpiece W.

In the initial stage of polishing the workpiece W, there may be a variation in film thickness within the surface of the workpiece W. For this reason, the measurement spectrum generated in the initial stage of polishing the workpiece W is likely to vary, and as a result, the classification result output from the recipe classification model 42 in the initial stage of polishing the workpiece W is also likely to vary.

Therefore, in one embodiment, the processing system 30 is configured to determine a recipe label that is majority (i.e., with the highest frequency) among the plurality of recipe labels indicated in a plurality of classification results output from the recipe classification model 42 within the predetermined decision time after polishing of the workpiece W is started.

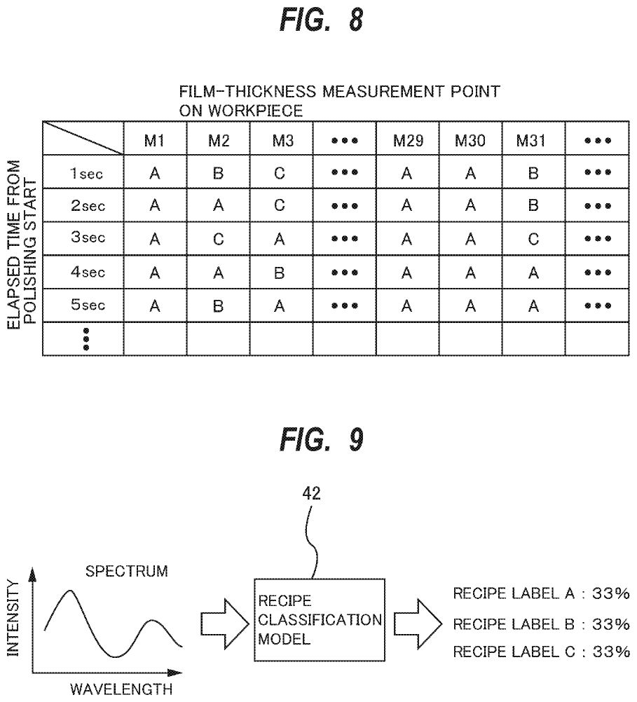

FIG. 8 is a table showing an example of a plurality of classification results output from the recipe classification model 42 within the predetermined decision time after the start of polishing of workpiece W. The numerical number of seconds shown in the table of FIG. 8 represents an elapsed time from the start of polishing of workpiece W, and M1, M2, M3, . . . shown in the table of FIG. 8 represent the film-thickness measurement points (see symbol M in FIG. 4) on the surface of workpiece W. Symbols A, B, and C in the table of FIG. 8 represent the recipe labels indicating the classification results output from the recipe classification model 42.

In the example shown in FIG. 8, among the recipe labels indicated in the classification results output from the recipe classification model 42 within the predetermined decision time (e.g., 5 seconds) after the start of polishing of the workpiece W, a majority recipe label, i.e., a recipe label with the highest frequency, among the recipe labels is the recipe label A. Therefore, the processing system 30 determines a film-thickness estimation recipe associated with the recipe label A. After the film-thickness estimation recipe is determined in this manner, the processing system 30 estimates film thicknesses at the plurality of film-thickness measurement points on the surface of the workpiece W using the film-thickness estimation recipe.

Before the predetermined decision time has elapsed, the processing system 30 estimates a film thickness at each film-thickness measurement point using the film-thickness estimation recipe associated with the recipe label obtained at each film-thickness measurement point. For example, at a film-thickness measurement point M3 when 2 seconds have elapsed since the start of polishing, the processing system 30 estimates the film thickness at the film-thickness measurement point M3 using the film-thickness estimation recipe associated with the recipe label C.

During polishing of the workpiece W, the polishing table 3 and the workpiece W rotate individually. Therefore, each time the polishing table 3 makes one rotation, the optical sensor head 25 moves across the surface of the workpiece W in a different path. On the other hand, each time the polishing table 3 makes one rotation, the optical sensor head 25 always moves across the center of the surface of the workpiece W (see FIG. 4). Typically, the surface structure of the workpiece W differs from region to region in the surface of the workpiece W. For example, memory cells may exist in one region in the surface of the workpiece W, and scribe lines may exist in another region. Due to such differences in the surface structure, the measurement spectrum of the reflected light may vary. The difference in the measurement spectrum may prevent the recipe classification model 42 from outputting a correct recipe label.

Thus, in one embodiment, the processing system 30 is configured to select a plurality of classification results obtained at film-thickness measurement points located within a central region of the surface of the workpiece W, and determine a majority recipe label, i.e., a recipe label with the highest frequency, among the plurality of recipe labels indicated in the plurality of selected classification results. As described above, the optical sensor head 25 moves across the center of the surface of the workpiece W each time the polishing table 3 makes one rotation (see FIG. 4).

In the example shown in FIG. 8, film-thickness measurement points M29, M30, and M31 are located within the central region of the surface of the workpiece W. The processing system 30 uses the recipe labels indicating the classification results obtained at these film-thickness measurement points M29, M30, and M31, and does not use the recipe labels indicating the classification results obtained at the other film-thickness measurement points. The measurement spectra of the reflected light from the film-thickness measurement points M29, M30, and M31 are spectra of the reflected light from the same surface structure regardless of lapse of the polishing time. Therefore, the recipe classification model 42 can correctly determine the film-thickness estimation recipe suitable for the workpiece W.

If the workpiece W being polished has a surface structure different from any of the plurality of reference workpieces used to create the training data, the measurement spectrum of the reflected light from that workpiece W is an unknown spectrum to the recipe classification model 42. Therefore, the recipe classification model 42 cannot determine a film-thickness estimation recipe suitable for that workpiece W. In such a case, the recipe classification model 42 outputs the same confidence scores for multiple recipe labels, as shown in FIG. 9.

Therefore, the processing system 30 is configured to input the measurement spectrum generated during polishing of the workpiece W to the recipe classification model 42, and when all of the plurality of confidence scores for the plurality of recipe labels output from the recipe classification model 42 are smaller than a threshold value, update the training data by adding, to the training data, the measurement spectrum of the reflected light from the workpiece W and a new recipe label indicating a new film-thickness measurement recipe determined based on that measurement spectrum, and perform the machine learning using the updated training data to update the recipe classification model 42. The new recipe label included in the updated training data is used as a correct label or ground-truth label in the machine learning. The new film-thickness measurement recipe is determined by a user based on the measurement spectrum.

The threshold value is preset in the processing system 30. The threshold value varies depending on the number of recipe labels used as correct labels (or ground-truth labels) in the training data. In the example shown in FIG. 9, the number of recipe labels is three, and therefore, the threshold value may be set to 34%. In another example, when the number of recipe labels is two, the threshold value may be set to 51%.

The measurement spectrum generated during polishing of a workpiece W having a different surface structure is an unknown spectrum to the recipe classification model 42, and therefore the recipe classification model 42 cannot determine a film-thickness estimation recipe. Therefore, the processing system 30 instructs the polishing apparatus to polish the workpiece W under a fixed polishing condition, and terminates polishing of the workpiece W when a preset polishing time is reached. An example of the fixed polishing condition includes a constant pressing force applied to the workpiece W from the polishing head 1.

Until polishing of the workpiece W is terminated, the processing system 30 generates a plurality of measurement spectra of the reflected light from the workpiece W and stores these measurement spectra in the memory 30a. The plurality of measurement spectra generated during polishing of the workpiece W can be used to determine the new film-thickness measurement recipe described above. Updating of the training data and updating of the recipe classification model 42 are performed after polishing of the workpiece W is terminated.

In a case where a measurement spectrum of reflected light from other workpiece being polished is an unknown spectrum to the recipe classification model 42, the processing system 30 adds that measurement spectrum to the training data to update the training data, and updates the recipe classification model 42 by performing machine learning using the updated training data in the same manner. The updated recipe classification model 42 can determine optimal film-thickness estimation recipes for a wider variety of workpieces.

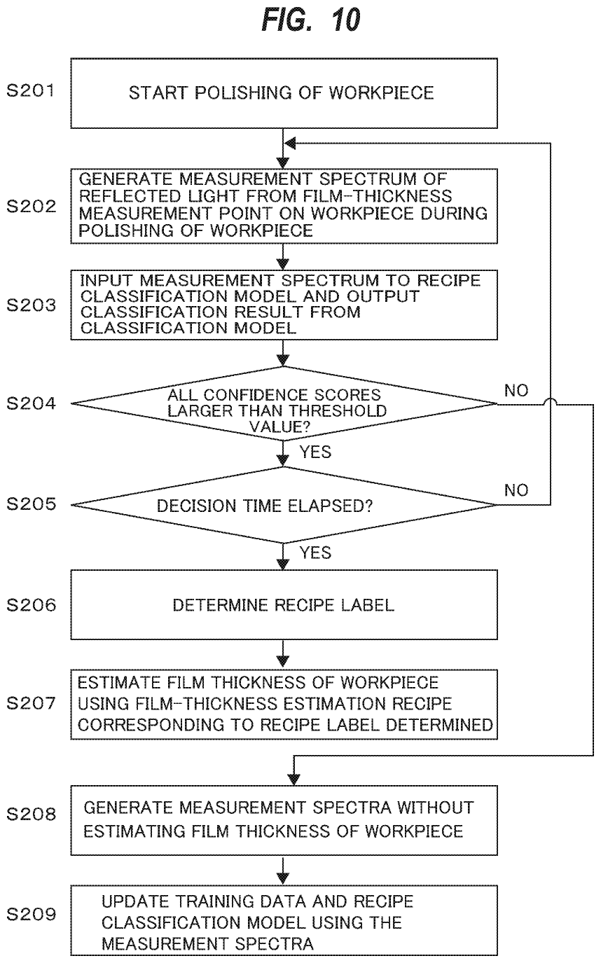

FIG. 10 is a flow chart illustrating an embodiment of estimating a film thickness of a workpiece W using the recipe classification model 42.

In step S201, polishing of the workpiece W by the polishing apparatus is started.

In step S202, while the workpiece W is being polished, the processing system 30 generates a measurement spectrum of the reflected light from a film-thickness measurement point on the workpiece W while the workpiece W is irradiated with the light from the optical sensor head 25. In one embodiment, the film-thickness measurement point on the workpiece W is located within a central region of the workpiece W.

In step S203, the processing system 30 inputs the measurement spectrum into the recipe classification model 42 and outputs a classification result from the recipe classification model 42 indicating one of the plurality of recipe labels.

In step S204, the processing system 30 determines whether all of the confidence scores of the plurality of recipe labels output from the recipe classification model 42 are larger than the threshold value.

In step S205, the processing system 30 repeats the steps S202 to S204 from the start of polishing the workpiece W until the predetermined decision time elapses.

In step S206, the processing system 30 determines a majority recipe label with the highest frequency among the plurality of recipe labels indicated in the plurality of classification results output from the recipe classification model 42 within the decision time.

In step S207, the processing system 30 estimates the film thickness of the workpiece W using the film-thickness estimation recipe corresponding to the recipe label determined in the step S206. In one embodiment, the processing system 30 inputs the measurement spectrum of the reflected light from the workpiece W being polished into the film-thickness estimation model 41, and outputs an estimated value of the film thickness from the film-thickness estimation model 41. In another embodiment, the processing system 30 determines, from a reference spectral library, a reference spectrum having a shape that is closest to a shape of the measurement spectrum of the reflected light, and determines the film thickness associated with the determined reference spectrum. In yet another embodiment, the processing system 30 performs a Fourier transform on the measurement spectrum of the reflected light, and determines the film thickness from a frequency spectrum obtained.

In step S208, if all of the confidence scores of the plurality of recipe labels are less than the threshold value in the step S204, the processing system 30 generates measurement spectra of the reflected light from the workpiece W until a polishing endpoint of the workpiece W is reached without estimating the film thickness of the workpiece W.

In step S209, the processing system 30 adds the plurality of measurement spectra obtained in steps S202 to S208 to the training data to update the training data, and further updates the recipe classification model 42 by performing the machine learning using the updated training data.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A film-thickness estimation method for a workpiece, comprising:
generating a plurality of reference spectra of reflected light from a plurality of reference workpieces while irradiating the plurality of reference workpieces with light during polishing of the plurality of reference workpieces;
creating training data containing the plurality of reference spectra and a plurality of recipe labels indicating a plurality of film-thickness estimation recipes determined for the plurality of reference workpieces;
performing machine learning using the training data to create a recipe classification model;
generating a measurement spectrum of reflected light from a film-thickness measurement point on a workpiece while irradiating the film-thickness measurement point with light during polishing of the workpiece;
inputting the measurement spectrum into the recipe classification model and outputting a classification result indicating one of the plurality of recipe labels from the recipe classification model;
determining one of the plurality of recipe labels based on the classification result; and
estimating a film thickness of the workpiece using a film-thickness estimation recipe corresponding to the determined recipe label.

2. The film-thickness estimation method for a workpiece according to claim 1, wherein determining one of the plurality of recipe labels based on the classification result comprises determining a recipe label that is majority among a plurality of recipe labels indicated in a plurality of classification results output from the recipe classification model within a predetermined decision time after start of polishing of the workpiece.

3. The film-thickness estimation method for a workpiece according to claim 1, wherein the classification result includes a plurality of confidence scores corresponding to the plurality of recipe labels, respectively.

4. The film-thickness estimation method for a workpiece according to claim 3, further comprising:
when all of the plurality of confidence scores are smaller than a threshold value, updating the training data by adding, to the training data, the measurement spectrum and a new recipe label indicating a new film-thickness measurement recipe determined based on the measurement spectrum; and
updating the recipe classification model by performing machine learning using the updated training data.

5. The film-thickness estimation method for a workpiece according to claim 1, wherein the film-thickness measurement point on the workpiece is located within a central region of a surface of the workpiece.

6. The film-thickness estimation method for a workpiece according to claim 1, wherein the plurality of reference spectra are spectra generated during initial stages of polishing of the plurality of reference workpieces.

7. The film-thickness estimation method for a workpiece according to claim 1, wherein each of the plurality of film-thickness estimation recipes includes a recipe parameter for use in film thickness estimation using a film-thickness estimation model created by machine learning.

8. A polishing apparatus for a workpiece, comprising:
a polishing table configured to support a polishing pad;
a polishing head configured to press a workpiece against the polishing pad to polish the workpiece;
an optical sensor head configured to irradiate a film-thickness measurement point on the workpiece with light and receive reflected light from the film-thickness measurement point during polishing of the workpiece; and
a processing system configured to generate a measurement spectrum of the reflected light, the processing system including:
training data containing a plurality of reference spectra of reflected light from a plurality of reference workpieces and a plurality of recipe labels indicating a plurality of film-thickness estimation recipes determined for the plurality of reference workpieces, respectively; and
a recipe classification model created by machine learning using the training data,
wherein the processing system is configured to:
input the measurement spectrum into the recipe classification model during polishing of the workpiece;
output a classification result indicating one of the plurality of recipe labels from the recipe classification model;
determine one of the plurality of recipe labels based on the classification result; and
estimate a film thickness of the workpiece using a film-thickness estimation recipe corresponding to the determined recipe label.
